(19) United States
(12) Patent Application Publication
(10) Pub. No.: US 2023/0071197 A1
(43) Pub. Date: Mar. 9, 2023

(54) METHOD OF FORMING AN UNDERLAYER WITH INCREASED EXTREME ULTRAVIOLET (EUV) SENSITIVITY AND STRUCTURE INCLUDING SAME

(71) Applicant: ASM IP Holding B.V., Almere (NL)

(72) Inventors: Arpita Saha, Espoo (FI); David de Roest, Leuven (BE); Charles Dezelah, Helsinki (FI); Michael Givens, Oud-Heverlee (BE)

(21) Appl. No.: 17/899,928

(22) Filed: Aug. 31, 2022

Related U.S. Application Data
(60) Provisional application No. 63/240,668, filed on Sep. 3, 2021.

(51) Int. Cl. G03F 1/56; G03F 7/16; G03F 7/004

(52) U.S. Cl. CPC G03F 1/56; G03F 7/167; G03F 7/0043

(57) ABSTRACT

Methods of forming structures including a photoresist absorber layer and structures including the photoresist absorber layer are disclosed. Exemplary methods include forming the photoresist absorber layer that includes an element having a relatively high extreme ultraviolet (EUV) sensitivity on a mass basis while having a relatively low EUV sensitivity on a mole basis.

### CROSS-REFERENCE TO RELATED APPLICATIONS

This application claims priority to U.S. Provisional Patent Application Ser. No. 63/240,668 filed Sep. 3, 2021 titled METHOD OF FORMING AN UNDERLAYER WITH INCREASED EXTREME ULTRAVIOLET (EUV) SENSITIVITY AND STRUCTURE INCLUDING SAME, the disclosure of which is hereby incorporated by reference in its entirety.

### FIELD OF INVENTION

The present disclosure generally relates to structures and to methods used in the formation of devices. More particularly, the disclosure relates to structures including or formed using a photoresist absorber layer (sometimes referred to as an underlayer or UL) with improved extreme ultraviolet (EUV) absorbance and to methods of forming such structures.

### BACKGROUND OF THE DISCLOSURE

During the manufacture of electronic devices, fine patterns of features can be formed on a surface of a substrate by patterning the surface of the substrate and etching material from the substrate surface using, for example, gas-phase etching processes. As a density of devices on a substrate increases, it generally becomes increasingly desirable to form features with smaller dimensions.

Photoresist is often used to pattern a surface of a substrate prior to etching. A pattern can be formed in the photoresist by applying a layer of photoresist to a surface of the substrate, masking the surface of the photoresist, exposing the unmasked portions of the photoresist to radiation, such as ultraviolet light, developing the exposed or unexposed portions of the photoresist to remove a portion (e.g., the unmasked or masked portion) of the photoresist, while leaving a portion of the photoresist on the substrate surface.

Recently, techniques have been developed to use extreme ultraviolet (EUV) wavelengths to develop patterns having relatively small pattern features. One limitation of methods using EUV is the relatively low flux of EUV photons and the resultant long exposure times and/or the inadequate exposure of the photo-sensitive materials that are responsible for creating contrast between exposed and unexposed areas of the photoresist.

Accordingly, structures for lowering EUV dose requirements and methods of forming such structures are desired. Any discussion of problems and solutions set forth in this section has been included in this disclosure solely for the purpose of providing a context for the present disclosure and should not be taken as an admission that any or all of the discussion was known at the time the invention was made.

### SUMMARY OF THE DISCLOSURE

Various embodiments of the present disclosure relate to structures including improved photoresist absorber layers (sometimes referred to as underlayers) and to methods of forming the layers and structures. While the ways in which various embodiments of the present disclosure address drawbacks of prior methods and structures are discussed in more detail below, in general, various embodiments of the disclosure provide structures that include a photoresist absorber layer with relatively high EUV sensitivity. The relatively high sensitivity allows for use of a relatively low dosage of EUV to obtain desired contrast between exposed and unexposed areas of the photoresist, which, in turn, allows for the formation of features with desired properties, such as small critical dimensions, which can be formed in a relatively cost-effective manner. In addition, only needing a relatively low dosage of EUV advantageously allows reducing exposure times, thereby increasing throughput of EUV exposures.

Exemplary EUV absorber layers include an element with relatively high EUV absorption on a mass basis while having a relatively low EUV absorption on a mole basis. Such absorber layers can be stand alone or part on an underlayer film stack. Use of such absorber layers can provide desired patterned features during EUV photoresist patterning, using relatively low EUV dosage during a step of exposing the photoresist to EUV radiation. Exemplary photoresist absorber layers can be formed using a cyclical process, such as atomic layer deposition or plasma-enhanced atomic layer deposition, which allows for precise control of a thickness of the photoresist absorber layer both on a surface of a substrate and from substrate to substrate.

In accordance with exemplary embodiments of the disclosure, a method of forming an extreme ultraviolet (EUV) absorber layer on a surface of a substrate is provided. An exemplary method includes providing a substrate within a reaction space of a gas-phase reactor, providing a precursor to the reaction space, and providing a reactant to the reaction space. The method further includes forming an absorber layer on a surface of the substrate within the reaction space. Significantly, the absorber layer includes an element having a photoabsorption cross section at 91.5 eV on a per mass basis greater than 8×10⁵ cm²/g, a photoabsorption cross section at 91.5 eV on a per mole basis less than 5×10⁶ cm²/mol, and a Pauling electronegativity of less than 2.

In some implementations of the method, the element has a photoabsorption cross section at 91.5 eV on a per mass basis greater than 10×10⁵ cm²/g while other embodiments may include elements with a photoabsorption cross section at 91.5 eV on a per mass basis greater than 12×10⁵ cm²/g or even greater than 14×10⁵ cm²/g to achieve a desired EUV sensitivity. For example, the element can be selected from the group consisting of: Mg, Na, and Al, and it may be useful for the absorber layer to be formed as a chalcogenide (e.g., to include O, S, Se, Te, or the like) or a halide (e.g., to include F, Cl, Br, I, or the like) of the element. In such implementations of the method, the heavier chalcogenides (e.g., S, Se, and Te) and halogens (e.g., Cl, Br, and I) would be used together with one of the lighter cation-forming elements. Chalcogenides in the form of oxides may be preferred in some cases because they are more likely to be air-stable. Fluorides can be useful as well in many applications, especially when a photoresist and an absorber layer are sequentially deposited without air break, e.g., in two separate reaction chambers of a single cluster tool. In other cases, though, oxyfluorides are another form for the absorber layer.

In these and other embodiments of the method, the absorber layer may further include a dopant to enhance EUV sensitivity, and this dopant may be a high-z element such as one selected from the group consisting of I, Te, Cs, Sb, Sn, In, Bi, Ag, Pb, Au, Pt, and Ir or the group consisting of I, Te, Cs, Sb, In, Bi, Ag, Pb, Au, Pt, and Ir. Further, it may be desirable to form the absorber layer such that the absorber layer includes both a cation forming element (e.g., Na, Mg, and Al) and an anion forming element (e.g., O and F). Additionally or alternatively, the method may also include a step of forming an EUV photoresist layer overlying the absorber layer, and, in such implementations of the method, the EUV photoresist layer may include nearly any EUV resist, which may be known in the arts, such as molecular resists, inorganic resists, and chemically amplified resists (CARs). In some cases, CARs are expected to be the most sensitive for these high-z layers, because the same effect does not happen with metal-containing photoresists The step of forming the absorber layer may be performed with a cyclical deposition process, such as atomic layer deposition or plasma-enhanced atomic layer deposition.

In accordance with further examples of the disclosure, structures suitable for forming patterned features using extreme ultraviolet (EUV) radiation are provided. The structures include a substrate and an absorber layer formed overlying the substrate. The absorber layer comprises an element selected from the group consisting of: F, Mg, Na, and Al. In such structures, the absorber layer may be an oxide or a fluoride of the element. In these or other embodiments of the structure the element has a photoabsorption cross section at 91.5 eV on a per mass basis greater than 8×10⁵ cm²/g, a photoabsorption cross section at 91.5 eV on a per mole basis less than 5×10⁶ cm²/mol, and a Pauling electronegativity of less than 2. The absorber layer may further include a dopant with a photoabsorption cross section at 91.5 eV on a per mole basis greater than 2×10⁶ cm²/mol. Additionally, the structure may include an EUV photoresist layer overlying the absorber layer.

In accordance with other examples of the disclosure, structures suitable for forming patterned features using extreme ultraviolet (EUV) radiation are provided. The structures include a substrate and an absorber layer formed overlying the substrate. The absorber layer comprises an element selected from the group consisting of Mn, Fe, Co, Ni, Cu, Zn, Ga, Ge, and As. In some implementations, the element has a photoabsorption cross section at 91.5 eV on a per mass basis greater than 6×10⁵ cm²/g and a photoabsorption cross section at 91.5 eV on a per mole basis less than 5×10⁶ cm²/mol. It may be useful in some of these structures for the absorber layer to be an oxide or a fluoride of the element.

In accordance with further examples of the disclosure, a system is provided. The system can be used to perform a method described herein and/or to form a structure as described herein.

These and other embodiments will become readily apparent to those skilled in the art from the following detailed description of certain embodiments having reference to the attached figures; the invention not necessarily being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a method in accordance with exemplary embodiments of the disclosure.

FIG. 2 illustrates a structure in accordance with exemplary embodiments of the disclosure.

FIG. 3 illustrates a system configured for executing a method as described herein.

FIG. 4 illustrates a direct plasma system for executing a method as described herein.

FIG. 5 illustrates an indirect plasma system for executing a method as described herein.

FIG. 6 illustrates a remote plasma system for executing a method as described herein.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

The description of exemplary embodiments of the present invention provided below is merely exemplary and is intended for purposes of illustration only; the following description is not intended to limit the scope of the invention disclosed herein. Moreover, recitation of multiple embodiments having stated features is not intended to exclude other embodiments having additional features or other embodiments incorporating different combinations of the stated features.

The present disclosure generally relates to methods of forming structures that include an extreme ultraviolet (EUV) absorber layer and to structures including the EUV absorber layer. Exemplary methods can be used to form structures with underlayers (absorber layers) with increased EUV sensitivity, which can result in lower EUV dosages used during photoresist exposure steps. The methods can be used to form structures with EUV absorber layers that allow for formation of patterned features with desired properties, such as small critical dimensions, reduced tapering and/or reduced roughness, compared to photoresist features formed using typical EUV photolithography techniques. Thus, methods described herein can provide for increased throughput of the manufacture of structures, reduced costs associated with the formation of the structures and/or devices formed using the structures, and/or a reduction of critical dimensions of features formed using the absorber layer and the photoresist layer.

As used herein, the term substrate may refer to any underlying material or materials including and/or upon which one or more layers can be deposited. A substrate can include a bulk material, such as silicon (e.g., single-crystal silicon), other Group IV materials, such as germanium, or compound semiconductor materials, such as GaAs, and can include one or more layers overlying or underlying the bulk material. For example, a substrate can include a patterning stack of several layers overlying bulk material. The patterning stack can vary according to application and can include, for example, a hardmask, such as a metal hardmask, an oxide hardmask, a nitride hardmask, a carbide hardmask, or an amorphous carbon hardmask. Further, the substrate can additionally or alternatively include various features, such as recesses, lines, and the like formed within or on at least a portion of a layer of the substrate.

In some embodiments, film refers to a layer extending in a direction perpendicular to a thickness direction. In some embodiments, layer refers to a material having a certain thickness formed on a surface or a synonym of film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. Further, a layer or film can be patterned and can be continuous or discontinuous.

In this disclosure, gas may include material that is a gas at normal temperature and pressure, a vaporized solid and/or a vaporized liquid, and may be constituted by a single gas or a mixture of gases, depending on the context. A gas other than the process gas, i.e., a gas introduced without passing through a gas distribution assembly, such as a showerhead, other gas distribution device, or the like, may be used for, e.g., sealing the reaction space, and may include a seal gas, such as a rare gas.

In some cases, such as in the context of deposition of material, the term precursor can refer to a compound or compounds that participates in the chemical reaction that produces another compound, and particularly to a compound that constitutes a film matrix or a main skeleton of a film, whereas the term reactant can refer to a compound, in some cases other than precursors, that reacts with the precursor, activates the precursor, modifies the precursor, or catalyzes a reaction of the precursor; a reactant may provide an element (e.g., a halide) to a film and become a part of the film. In some cases, the terms precursor and reactant can be used interchangeably. The term inert gas refers to a gas that does not take part in a chemical reaction to an appreciable extent and/or a gas that interacts with a precursor or reactant when, for example, RF or microwave power is applied, but unlike a reactant, it may not become a part of a film matrix to an appreciable extent.

The term cyclic deposition process or cyclical deposition process may refer to the sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a cyclical CVD component. In other cases, the processing techniques may include a plasma process such as plasma enhanced CVD (PECVD) or plasma enhanced ALD (PEALD). Plasma processes may be desirable as they use chemical precursors, such as in thermal ALD, but these processes also cycle an RF-plasma creating the necessary chemical reactions in a highly controlled manner.

The term atomic layer deposition may refer to a vapor deposition process in which deposition cycles, typically a plurality of consecutive deposition cycles, are conducted in a process chamber. The term atomic layer deposition, as used herein, is meant to include processes designated by related terms, such as chemical vapor atomic layer deposition, atomic layer epitaxy (ALE), molecular beam epitaxy (MBE), gas source MBE, or organometallic MBE, and chemical beam epitaxy when performed with alternating pulses of precursor(s)/reactive gas(es), and purge (e.g., inert carrier) gas(es).

Generally, for ALD processes, during each cycle, a precursor is introduced to a reaction chamber and is chemisorbed to a deposition surface (e.g., a substrate surface that can include a previously deposited material from a previous ALD cycle or other material), forming about a monolayer or sub-monolayer of material that does not readily react with additional precursor (i.e., a self-limiting reaction). Thereafter, in some cases, a reactant may subsequently be introduced into the process chamber for use in converting the chemisorbed precursor to the desired material on the deposition surface. The reactant can be capable of further reaction with the precursor. Purging steps can be utilized during one or more cycles, e.g., during each step of each cycle, to remove any excess precursor from the process chamber and/or remove any excess reactant and/or reaction byproducts from the reaction chamber.

As used herein, the term purge or purging may refer to a procedure in which gas flow is stopped or a procedure involving continual provision of a carrier gas whereas precursor flow is intermittently stopped. For example, a purge may be provided between a precursor pulse and a reactant pulse, thus avoiding, or at least reducing, gas phase interactions between the precursor and the reactant. It shall be understood that a purge can be affected either in time or in space or both. For example, in the case of temporal purges, a purge step can be used, e.g., in the temporal sequence of providing a precursor to a reactor chamber, providing a purge gas to the reactor chamber, and providing a reactant to the reactor chamber, wherein the substrate on which a layer is deposited does not move. In the case of spatial purges, a purge step can take the form of moving a substrate from a first location to which a precursor is supplied, through a purge gas curtain, to a second location to which a reactant is supplied.

In this disclosure, any two numbers of a variable can constitute a workable range of the variable, and any ranges indicated may include or exclude the endpoints. Additionally, any values of variables indicated (regardless of whether they are indicated with about or not) may refer to precise values or approximate values and include equivalents, and may refer to average, median, representative, majority, etc. in some embodiments. Further, in this disclosure, the terms including, constituted by and having can refer independently to typically or broadly comprising, comprising, consisting essentially of, or consisting of in some embodiments. Further, the term comprising can include consisting of or consisting essentially of. In accordance with aspects of the disclosure, any defined meanings of terms do not necessarily exclude ordinary and customary meanings of the terms.

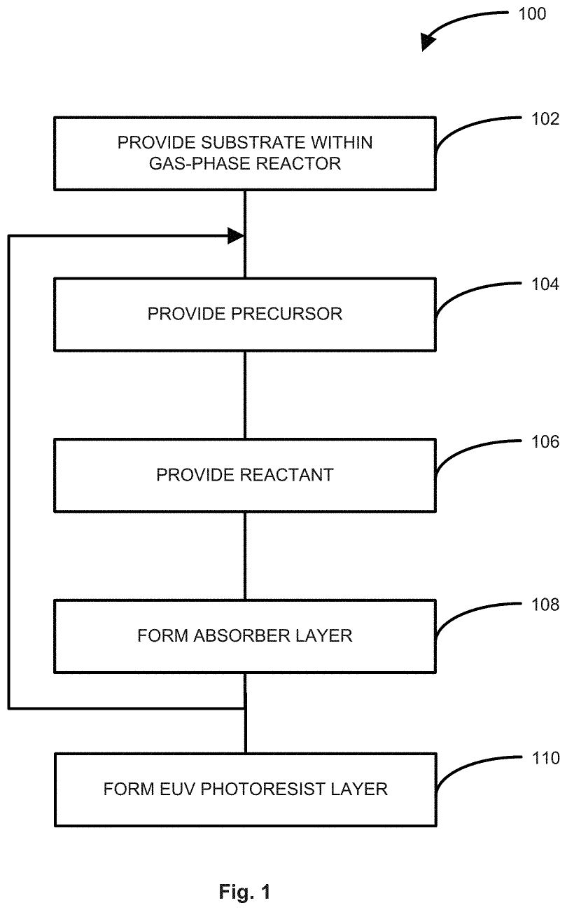

Turning now to the figures, FIG. 1 illustrates a method 100 in accordance with exemplary embodiments of the disclosure. Method 100 can be used for forming an extreme ultraviolet (EUV) absorber layer on a surface of a substrate. Method 100 includes the steps of providing a substrate within a reaction space of a gas-phase reactor (step 102), providing a precursor to the reaction space (step 104), providing a reactant to the reaction space (step 106), and forming an absorber layer (step 108). Method 100 can also include a step of forming an EUV photoresist layer (step 110) overlying the absorber layer.

Exemplary methods can be or include cyclical deposition methods, such as ALD methods, and can include, in some useful embodiments, indirect, direct, and remote plasma methods, which may include super cycle processes in which sub-cycles may be selectively repeated to enhance tuning (e.g., to achieve a desired amount or concentration of a desired element in the absorber or underlayer or the like). The high-z underlayers described herein can be formed using CVD, thermal ALD, PECVD, or PEALD. The steps 104, 106, and 108 may be performed contemporaneously in some desirable implementations of the method 100 and/or in differing orders. For example, the steps of exposing the substrate to precursor and reactant may be performed either in an alternating or simultaneous manner, and this results in absorber formation such that absorber may occur contemporaneously with precursor and reactant exposure.

Step 102 includes providing a substrate, such as a substrate described herein, within a reaction space of a gas-phase reactor. The substrate can include one or more layers, including one or more material layers, to be etched. By way of examples, the substrate can include a deposited oxide, a native oxide, or an amorphous carbon layer to be etched. The substrate can include several layers underlying the material layer(s) to be etched.

During step 104, a precursor is provided to the reaction space. Exemplary precursors can include one or more (e.g., metallic) elements with a relatively high EUV cross section on a mass basis (which may be provided as a photoabsorption cross section at 91.5 eV on a per mass basis) while having a relatively low EUV cross section on a mole basis (which may be provided as a photoabsorption cross section at 91.5 eV on a per mole basis).

For example, the element may have a photoabsorption cross section at 91.5 eV on a per mass basis greater than 8×10⁵ cm²/g while having a photoabsorption cross section at 91.5 eV on a per mole basis less than 5×10⁶ cm²/mol. In this example, the precursor can include one or more of F, Mg, Na, and Al. In some cases, it may be useful that the element be chosen to have a Pauling electronegativity of less than 2, and, then, the precursor may include one or more of Mg, Na, and Al. In some cases, though, the element has a photoabsorption cross section at 91.5 eV on a per mass basis greater than 10×10⁵ cm²/g, greater than 12×10⁵ cm²/g, or even greater than 14×10⁵ cm²/g.

In other examples, the element may have a photoabsorption cross section at 91.5 eV on a per mass basis greater than 5×10⁵ cm²/g while having a photoabsorption cross section at 91.5 eV on a per mole basis less than 5×10⁶ cm²/mol. In this example, the precursor can include one or more of Mn, Fe, Co, Ni, Cu, Zn, Ga, Ge, and As. In some cases, though, the element in the absorber layer has a photoabsorption cross section at 91.5 eV on a per mass basis greater than 6×10⁵ cm²/g, and the precursor may include one or more of Mn, Fe, Co, Ni, Cu, and Zn.

More specifically, the precursors may comprise ligands including a cyclopentadienyl, alkylamide, alkoxide, alkyl, halide, amidinate, diazadiene, and carbonyl. In some cases, the metal precursor comprises an alkylamido compound. Exemplary metal alkylamido compounds include a metal center and one or more independently selected (e.g., C1-C4) alkyl amine ligands. Particular examples include M(NMe₂)₄, M(NEt₂)₄, and M(NEtMe)₄.

Exemplary metal alkoxide compounds include M(OMe)₄, M(OEt)₄, M(OiPr)₄, M(OtBu)₄, MO(OMe)₃, MO(OEt)₃, MO(OiPr)₃, and MO(OtBu)₃. Additional metal alkoxide compounds include variations of these compounds, where other alkoxy ligands are used.

Exemplary metal cyclopentadienyl compounds include MCp₂Cl₂, MCp₂, and MCp₂(CO)₄. Additional exemplary cyclopentadienyl compounds include variations of these compounds, where Cp is either unsubstituted or bearing one or more alkyl groups, e.g., MeCp, EtCp, iPrCp, and the like.

By way of particular examples, the precursor can include one or more of a metal halide, such as a Pb halide (e.g., PbF₂), a Sb halide (e.g., SbCl₃), a Bi halide (e.g., BiCl₃, BiF₃, Bil₃), an indium halide (e.g., InF₃, InCl₃); a metal silylamide, e.g., a metal bis(trimethylsilyl)amide (btsa) (e.g., Pb-silylamide (e.g., Pb(btsa)₂)), a Bi-silylamide (e.g., Bi(btsa)₂); a metal trimethylsilyl precursor (e.g., Te(TMS)₂); a metal alkoxide (e.g., cesium tert-butoxide (CsO^{t}Bu), a Bi-alkoxide, antimony(III) ethoxide (Sb(OEt)₃); a metal amine or amino precursor, such as Bi(NMe₂)₃, Bi(NEtMe)₃), Sb(NMe₂)₃, Pb[N(SiMe₃)₂]₂; a metal cyclopentadienyl precursor (e.g., InCp); an alkyl metal precursor, such as trimethylindium (TMI), triethylindium (TEO, or the like.

By way of additional examples, a metal alkylsilylamide or metal silylamide compound can be represented by the general formula (i), where R1-R6 are each independently selected from a C1-C4 alkyl group.

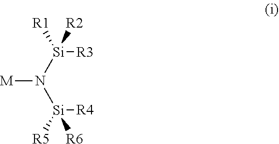

A temperature within a reaction space during step 104 can be, for example, between about 20° C. and about 200° C. A pressure within the reaction chamber during step 104 can be about 140 Pa to about 1300 Pa. A flowrate of the precursor can be between about 200 to about 2000 sccm. A duration of a pulse of introducing the precursor to the reaction chamber can be between about 0.1 and about 15 seconds.

During step 106, a reactant is provided to the reaction space. In accordance with examples of the disclosure, the reactant includes a halide, such as one or more of F, Cl, Br, and I. Particular exemplary halides suitable for use as a reactant include HF, TiF₄, SnI₄, CH₂I₂, HI, I₂, and the like. In some cases, another precursor can be a reactant. In such cases, the reactant can include any of the precursors noted above.

In addition, oxygen reactants, nitrogen reactants, carbon reactants, and reducing reactants may be used. Suitable oxygen reactants include O₂, O₃, and H₂O. Suitable nitrogen reactants include N₂, NH₃, N₂H₂, and forming gas. Suitable carbon reactants include alkyls such as CH₄. Suitable reduction reactants include H₂. If other elements are desired, the reactant may be chosen to suit the need. For example, in case Te is desired, one could use an alkoxyde such as Te(OR)₄, a trialkylsilyl such as Te(TMS)₂ or Te(TES)₂, dialkyltellurides (such as Te(iPr)₂, Te(tBu)₂, and the like) or elemental Te, where R stands for an alkyl such as a low C alkyl (e.g., one containing 1 to 4 C atoms), where TMS stands for trimethylsilyl, where TES stands for triethylsilyl (or more broadly for trialkylsilyl). In case a sulfur (S) containing film is desired, one could use a sulfur reactant such as H₂S, dialkylsulfide, dialkyldisulfide, alkylthiol, an alkylsilyl sulfur compound such as (TMS)₂S, a sulfur halide such as S₂Cl₂, or elemental S. In case a selenium-containing film is desired, the reactant can comprise H₂Se, alkylselenol, dialkylselenide, dialkyldiselenide, bis(trialkylsilyl)selenide, or elemental Se.

A temperature and pressure within the reaction chamber during step 106 can be the same or similar to the temperature and/or pressure noted above in connection with step 104. A flowrate of the reactant can be between about 100 to about 2000 sccm. A duration of a pulse of introducing the reactant to the reaction chamber can be between about 0.1 and about 30 seconds. As illustrated in FIG. 1, steps 104 and 106 can be repeated one or more times to form the absorber layer (step 108).

Various combinations of precursors and corresponding reactants suitable for use in steps 104 and 106 can be used to form the absorber layer. For example, in some cases, the absorber layer includes a chalcogenide or a halide, such as an oxide or halide comprising one or more of F, Na, Mg, or Al in some examples or comprising one or more of Mn, Fe, Co, Ni, Cu, Zn, Ga, Ge, and As in other examples (or one or more elements form either of these groups of elements). In some cases, solid oxides and halides of metals, such as metals noted herein, can provide better cross-sectional absorbance of EUV radiation, in which both the metal and the non-metal provide relatively high cross-sectional absorbance, compared to typical absorber layers. In some cases, increased absorbance is achieved by an increased number of oxides per mole and/or the oxide providing increased absorbance compared to other materials.

In some useful embodiments, the element can be selected from the group consisting of: Mg, Na, and Al (or one or more of the elements described above), and it may be useful for the absorber layer to be formed as a chalcogenide (e.g., to include 0, S, Se, Te, or the like) or a halide (e.g., to include F, Cl, Br, I, or the like) of the element. In such implementations of the method, the heavier chalcogenides (e.g., S, Se, and Te) and halogens (e.g., Cl, Br, and I) would be used together with one of the lighter cation-forming elements. Chalcogenides in the form of oxides may be preferred in some cases because they are more likely to be air-stable. Fluorides can be useful as well in many applications, especially when a photoresist and an absorber layer are sequentially deposited without air break, e.g., in two separate reaction chambers of a single cluster tool. In other cases, though, oxyfluorides are another form for the absorber layer.

Halogenating chemistries may include sulfur halides such as sulfur tetrafluoride (SF₄), 2,2- fluorinated dialkylimidazolidines such as Difluoro-1,3-dimethylimidazolidine (DFI), fluorosulfonic acid (SO₃HF), polyfluoroalkylamines such as N,N-diethyl-(1,1,2,3,3,3-hexafluoropropyl)amine, and polyfluoroalkenylamines such as N,N-diethyl-(E)-pentafluoropropenylamine. Other halogenating chemistries that may be used include: (1) alkyl bromides and alkyl iodides, including 1,1-dibromoalkanes, 1,2-dibromoalkanes, 1,1-diiodoalkanes, and 1,2-diiodoalkanes; (2) aryl bromides and aryl iodides, including version containing multiple bromine or iodine atoms attached to an arene. Examples include bromobenzene and iodobenzene; (3) dihalogen molecules, e.g., Br₂, I₂, Cl-Br, Cl-I, or Br-I; (4) hydrohalogen molecules, e.g., HBr or HI; (5) acyl bromides and acyl iodides, including oxalyl bromide and oxalyl iodide; (6) bromosilanes and iodosilanes, including embodiments with multiple silicon atoms and/or multiple halogen atoms such as SiBr₄, SiI₄, SiH₂Br₂, SiH₂I₂, and similar; (7) thionyl bromide and thionyl iodide; (8) volatile metal halides, such as SnBr₄, SnI₄, AlBr₃, AlI₃, TiBr₄, TiI₄, and similar; (9) molecules containing a P-Br or P-I bond, such as PBr₃, PBr₅, POBr₃, or POI₃; (10) molecules containing a N-Br or N-I bond, such as N-bromosuccinimide or N-iodosuccinimide; (11) alkyl hypobromites and alkyl hypoiodites, for example tert-butyl hypobromite; and (12) volatile halogen salts of bromine or iodine, for example ammonium bromide, ammonium iodide, pyridinium bromide, and pyridinium iodide.

In some implementations, alfa-fluoroalkylamines may be utilized. For example, in some embodiments, the α-fluoroamine comprises a compound containing at least one carbon atom that is bonded to both a nitrogen atom and a fluorine atom. More specifically, in some embodiments, the α-fluoroamine has a formula of R₂NCF₂R′, where the R groups are independently any C1 to C6 hydrocarbon and the R′ group is any one of the following: a C1-C6 hydrocarbon, a partially fluorinated C1-C6 hydrocarbon, a perfluoroalkyl group, a perfluoroaryl group, or an —NR₂ group. In some embodiments, the R or R′ groups are cyclic. In some embodiments, the cyclic R or R′ groups incorporate the “NCF2” fragment of the α-fluoroamine. In some embodiments, the α-fluoroamine is chosen from the group: 1,1,2,2,-tetrafluoroethyl-N,N-dimethylamine; 2,2-Difluoro-1,3-dimethylimidazolidine; N,N-Diethyl-1,1,2,3,3,3-hexafluoro-1-propanamine; and 2-Chloro-N,N-diethyl-1,1,2-trifluoroethanamine.

In some embodiments, the chlorinating agent comprises a C-Cl bond. In some embodiments, the chlorinating agent is chosen from the group: an acyl halide; oxalyl chloride; and acetyl chloride. In some embodiments, the chlorinating agent comprises a S-Cl bond. In such embodiments, the chlorinating agent may be selected from the group: thionyl chloride; sulfuryl chloride; an alkyl sulfonyl chloride; disulfur dichloride, S₂Cl₂; and sulfur dichloride, SCl₂.

In some embodiments, the chlorinating agent comprises a P-Cl bond. In such embodiments, the chlorinating agent may be selected from the group: PCl₃; PCl₅; and POCl₃. In some embodiments, the chlorinating agent is a dialkylphosphinic chloride (e.g., R₂POCl, R=alkyl). In some embodiments, the chlorinating agent is a diarylphosphinic chloride (e.g., R₂POCl, R=aryl). In some embodiments, the chlorinating agent is an alkylphosphonic dichloride (e.g., RPOCl₂, R=alkyl). In some embodiments, the chlorinating agent is an arylphosphonic dichloride (e.g. RPOCl₂, R=aryl). In some embodiments, the chlorinating agent comprises a N—Cl bond. In some embodiments, the chlorinating agent is N-chlorosuccinimide. In some embodiments, the chlorinating agent comprises a O-Cl bond. In some embodiments, the chlorinating agent is an alkyl hypochlorite. In some embodiments, the chlorinating agent is tert-butyl hypochlorite.

In these and other embodiments of the method 100, the absorber layer may further include a dopant to enhance EUV sensitivity, and this dopant may be a high-z element such as one selected from the group consisting of I, Te, Cs, Sb, Sn, In, Bi, Ag, Pb, Au, Pt, and Ir. Alternatively, the dopant may be a high-z element such as one selected from the group consisting of I, Te, Cs, Sb, In, Bi, Ag, Pb, Au, Pt, and Ir. Further, it may be desirable to form the absorber layer such that the absorber layer includes both a cation forming element (e.g., Na, Mg, and Al) and an anion forming element (e.g., O and F). The step of forming the absorber layer may be performed with a cyclical deposition process, such as atomic layer deposition.

As illustrated in FIG. 1, once a desired thickness of the absorber layer via steps 104-108 is obtained, an optional EUV photoresist layer can be formed over the absorber layer (e.g., in direct contact with the absorber layer) during step 110. In such implementations of the method, the EUV photoresist layer may include any suitable photoresist, such as a molecular, metal oxide, or chemically amplified photoresist. In addition, it may be desirable to etch or strip the absorber layer from the substrate surface. Therefore, the absorber layer may desirably include material that can form soluble or volatile compounds when reacted with an etchant.

In some cases, the absorber layer comprises two or more elements selected from the group consisting of F, Mg, Na, Al, Mn, Fe, Co, Ni, Cu, Zn, Ga, Ge, and As. In accordance with other examples, the absorber layer is doped (e.g., during step 104, 106, and/or 108) to include a dopant or material useful for increasing the EUV sensitivity. For example, some embodiments of the method 100 include doping the absorber layer with an element with a high atomic number (z), which also has a high EUV absorption on a per mole basis, e.g., a EUV cross section (σ_{α}) greater than 2×10⁶ cm²/mol. These dopants may be selected so as to include one or more of Sb, Sn, In, Bi, Ag, Pt, Ir, Pb, Au, and Cs.

The absorber layers which are described herein may, for example, be deposited using a thermal cyclical (e.g., ALD) or a thermal CVD method. Alternatively, the absorber layers that are described herein may be deposited using cyclical plasma (e.g., plasma ALD) or plasma pulsed-CVD—e.g., by activating (directly or remotely) a reactant and/or precursor. Both approaches may suitably provide for the deposition of thin (5 nm) absorber layers with low non-uniformity.

In accordance with examples of the disclosure, the absorber layer includes at least one element having a photoabsorption cross section at 91.5 eV on a per mass basis greater than 8×10⁵ cm²/g while having a relatively low EUV cross section on a mole basis. The absorber layer may suitably include additional elements, such as additional metals (including high-z materials) or oxygen. Particular examples of materials suitable for the absorber layer are provided above. A thickness of the absorber layer formed during step 104 can be less than 10 nm or less than 5 nm.

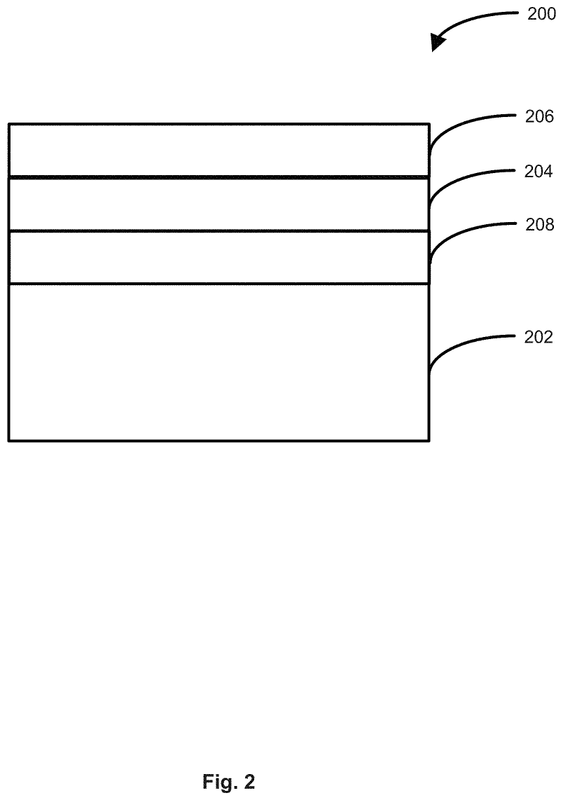

FIG. 2 illustrates a structure 200 in accordance with exemplary embodiments of the disclosure. Structure 200 can be formed using, for example, method 100. As illustrated, structure 200 includes a substrate 202, an absorber layer 204, and optionally one or more of a material layer 208, and a capping layer 206. Material layer 208 and EUV photoresist layer 206 can be used to provide desired stability to absorber layer 204 and/or for other reasons. Substrate 202 can include a substrate as described above. By way of examples, substrate 202 can include a semiconductor substrate and can include one or more layers. Further, as noted above, substrate 202 can include various topologies, such as recesses, lines, and the like formed within or on at least a portion of a layer of the substrate.

Absorber layer 204 can include an absorber layer formed in accordance with a method described herein (e.g., method 100) and/or comprise absorber material as described herein and/or have properties as described herein. A thickness of absorber layer 204 can depend on a composition of absorber layer 204, a thickness of and/or composition of material layer 208, a thickness of and/or composition of photoresist layer 206, a type of photoresist, and the like. In accordance with examples of the disclosure, absorber layer 204 has a thickness of less than 10 nm or less than or about 5 nm.

Material layer 208 can be formed of, for example, a hard mask. A hard mask can be any layer that provides etch contrast with the underlying layers. One possible hard mask is amorphous carbon. In other embodiments, the material layer 208 may include metals, semiconductors and their alloys, oxides, nitrides, and carbides. A thickness of material layer 208 can be from about 0.1 to about 10 nm. Photoresist layer 206 can be formed of, for example, a molecular resist, a metal oxide resist, or a chemically amplified resist. A thickness of photoresist layer 206 can be from about 5 to about 40 nm.

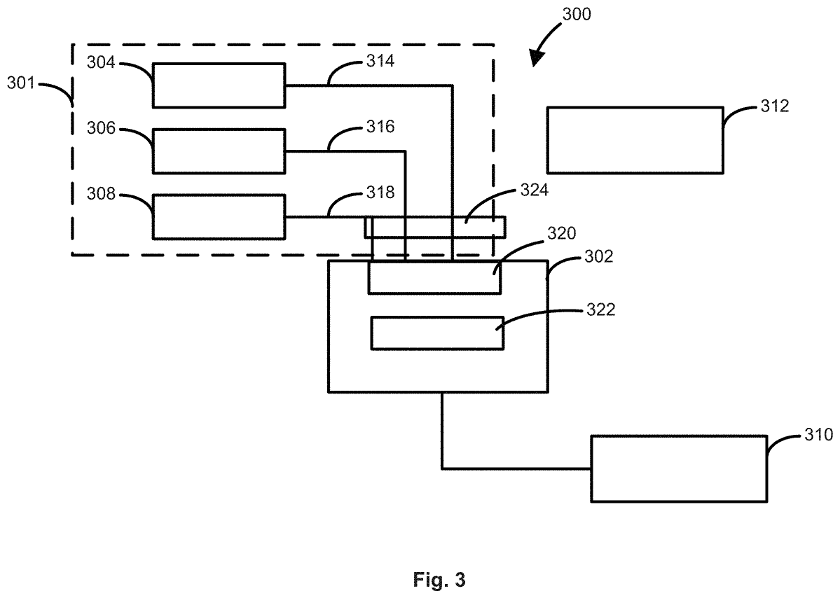

FIG. 3 schematically illustrates a system 300 in accordance with examples of the disclosure. System 300 can be used to perform a method as described herein and/or to form a structure or a portion thereof as described herein. In the illustrated example, system 300 includes one or more reaction chambers 302, a precursor injector system 301, a precursor vessel 304, a reactant vessel 306, an auxiliary reactant source 308, an exhaust source 310, and a controller 312. In some cases, though, it will be understood that some reactants, such as O₂, N₂, Hz, He, and Ar, are very common and are used throughout a fabrication. Accordingly, they may not be necessarily stored in a vessel inside the tool but may, instead, be provided from a central storage unit (not shown, which may be a pressurized vessel) via gas lines to the tools in the fabrication system 300. System 300 may include one or more additional gas sources (not shown), such as an inert gas source, a carrier gas source and/or a purge gas source. Reaction chamber 302 can include any suitable reaction chamber, such as an ALD or CVD reaction chamber as described herein.

Precursor vessel 304 (sometimes a metal precursor vessel) can include a vessel and one or more precursors as described herein including metal precursors—alone or mixed with one or more carrier (e.g., inert) gases. Reactant source vessel 306 can include a vessel and one or more reactants (e.g., oxide reactants, halide reactants, and the like) as described herein—alone or mixed with one or more carrier gases. Auxiliary reactant source 308 can include an auxiliary reactant or a precursor as described herein. Although illustrated with three source vessels 304-308, system 300 can include any suitable number of source vessels to provide the element with a high EUV absorption on a per mass basis and other materials, such as doping materials, in some implementations. Source vessels 304-308 can be coupled to reaction chamber 302 via lines 314-318, which can each include flow controllers, valves, heaters, and the like. In some embodiments, a vessel is heated so that a precursor or a reactant reaches a desired temperature. Each vessel may be heated to a different temperature, according to the precursor or reactant properties, such as thermal stability and volatility. Exhaust source 310 can include one or more vacuum pumps.

Controller 312 includes electronic circuitry and software to selectively operate valves, manifolds, heaters, pumps, and other components included in system 300. Such circuitry and components operate to introduce precursors, reactants, and purge gases from the respective sources. Controller 312 can control timing of gas pulse sequences, temperature of the substrate and/or reaction chamber 302, pressure within the reaction chamber 302, and various other operations to provide proper operation of the deposition or reactor system 300. Controller 312 can include control software to electrically or pneumatically control valves to control flow of precursors, reactants, and purge gases into and out of the reaction chamber 302. Controller 312 can include modules, such as a software or hardware component, which perform certain tasks. A module may be configured to reside on the addressable storage medium of the control system and be configured to execute one or more processes.

In the illustrated example, system 300 also includes a gas distribution assembly (e.g., a showerhead) 320 and a susceptor or substrate holder 322 (which can include an electrode and/or a heater) for receiving and supporting a substrate (e.g., a wafer). In accordance with some examples of the disclosure, system 300 can also include a remote plasma unit 324 to activate one or more reactants, precursors, and/or inert gases.

Other configurations of system 300 are possible, including different numbers and kinds of precursor and reactant sources. Further, it will be appreciated that there are many arrangements of valves, conduits, precursor sources, and auxiliary reactant sources that may be used to accomplish the goal of selectively and in a coordinated manner feeding gases into reaction chamber 302. Further, as a schematic representation of a deposition system, many components have been omitted for simplicity of illustration, and such components may include, for example, various valves, manifolds, purifiers, heaters, containers, vents, and/or bypasses.

During operation of deposition assembly 300, substrates, such as semiconductor wafers (not illustrated), are transferred from, for example, a substrate handling system to reaction chamber 302. Once substrates are transferred to reaction chamber 302, one or more gases from gas sources, such as precursors, reactants, carrier gases, and/or purge gases, are introduced into reaction chamber 302. In some embodiments, the precursor is supplied in pulses, the reactant is supplied in pulses and the reaction chamber is purged between consecutive pulses of precursor and reactant.

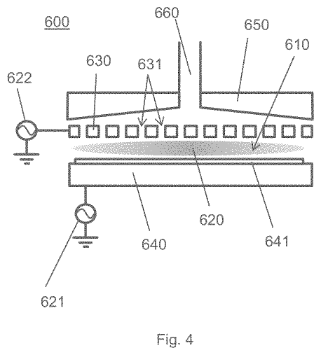

Direct, indirect, and remote plasma depositions can be used as well, either in ALD, CVD, hybrid mode, as shown in with the systems 600, 700, and 800 in FIGS. 4-6, respectively. Various pulsing schemes featuring super cycles made up of two separate sub-cycles can be used. For example, a PEALD process may tune concentrations or amounts of a desired element using a super cycle process (e.g., sub-cycle 1: In precursor pulse, O reactant pulse; sub-cycle 2: Sn precursor pulse, O reactant pulse; with each repeated as useful for tuning in on a desired amount of any particular element).

FIG. 4 shows a schematic representation of an embodiment of a direct plasma system 600 that is operable or controllable to perform the fabrication processes or methods as described herein. The system 600 includes a reaction chamber 610 in which a plasma 620 is generated. In particular, the plasma 620 is generated between a showerhead injector 630 and a substrate support 640 supporting a substrate or wafer 641.

In the configuration shown, the system 600 includes two alternating current (AC) power sources: a high frequency power source 621 and a low frequency power source 622. In the configuration shown, the high frequency power source 621 supplies radio frequency (RF) power to the showerhead injector, and the low frequency power source 622 supplies an alternating current signal to the substrate support 640. The radio frequency power can be provided, for example, at a frequency of 13.56 MHz or higher. The low frequency alternating current signal can be provided, for example, at a frequency of 2 MHz or lower.

Process gas comprising precursor, reactant, or both, is provided through a gas line 660 to a conical gas distributor 650. The process gas then passes via through holes (631) in the showerhead injector 630 to the reaction chamber 610. Whereas the high frequency power source 621 is shown as being electrically connected to the showerhead injector and the low frequency power source 622 is shown as being electrically connected to the substrate support 640, other configurations are possible as well. For example, in some embodiments (not shown), both the high frequency power source and the low frequency power source can be electrically connected to the showerhead injector; both the high frequency power source and the low frequency power source can be electrically connected to the substrate support; or both the high frequency power source can be electrically connected to the substrate support, and the low frequency power source can be electrically connected to the showerhead injector.

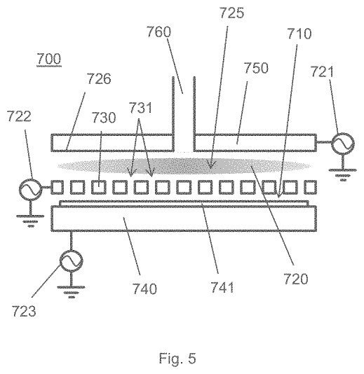

FIG. 5 shows a schematic representation of another embodiment of an indirect plasma system 700 operable or controllable to perform the methods as described herein. The system 700 includes a reaction chamber 710, which is separated from a plasma generation space 725 in which a plasma 720 is generated. In particular, the reaction chamber 710 is separated from the plasma generation space 725 by a showerhead injector 730, and the plasma 720 is generated between the showerhead injector 730 and a plasma generation space ceiling 726.

In the configuration shown, the system 700 includes three alternating current (AC) power sources: a high frequency power source 721 and two low frequency power sources 722, 723 (i.e., a first low frequency power source 722 and a second low frequency power source 723). In the configuration shown, the high frequency power source 721 supplies radio frequency (RF) power to the plasma generation space ceiling, the first low frequency power source 722 supplies an alternating current signal to the showerhead injector 730, and the second low frequency power source 723 supplies an alternating current signal to the substrate support 740. A substrate 741 is provided on the substrate support 740. The radio frequency power can be provided, for example, at a frequency of 13.56 MHz or higher. The low frequency alternating current signal of the first and second low frequency power sources 722, 723 can be provided, for example, at a frequency of 2 MHz or lower.

Process gas comprising precursor, reactant, or both, is provided through a gas line 760 that passes through the plasma generation space ceiling 726 to the plasma generation space 725. Active species such as ions and radicals generated by the plasma 725 from the process gas pass via through holes 731 in the showerhead injector 730 to the reaction chamber 710.

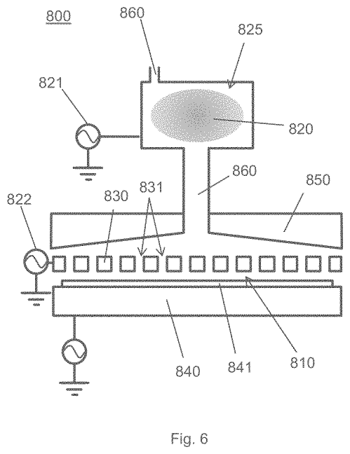

FIG. 6 shows a schematic representation of an embodiment of a remote plasma system 800 operable or controllable to perform the fabrication methods or processes as described herein. The system 800 includes a reaction chamber 810, which is operationally connected to a remote plasma source 825 in which a plasma 820 is generated. Any sort of plasma source can be used as a remote plasma source 825, for example an inductively coupled plasma, a capacitively coupled plasma, or a microwave plasma. In particular, active species are provided from the plasma source 825 to the reaction chamber 810 via an active species duct 860 to a conical distributor 850 via through holes 831 in a shower plate injector 830 to the reaction chamber 810. Thus, active species can be provided to the reaction chamber in a uniform way.

In the configuration shown, the system 800 includes three alternating current (AC) power sources: a high frequency power source 821 and two low frequency power sources 822, 823 (e.g., a first low frequency power source 822 and a second low frequency power source 823. In the configuration shown, the high frequency power source 821 supplies radio frequency (RF) power to the plasma generation space ceiling, the first low frequency power source 822 supplies an alternating current signal to the showerhead injector 830, and the second low frequency power source 823 supplies an alternating current signal to the substrate support 840. A substrate 841 is provided on the substrate support 840. The radio frequency power can be provided, for example, at a frequency of 13.56 MHz or higher. The low frequency alternating current signal of the first and second low frequency power sources 822, 823 can be provided, for example, at a frequency of 2 MHz or lower.

In some embodiments (not shown), an additional high frequency power source can be electrically connected to the substrate support. Thus, a direct plasma can be generated in the reaction chamber. Process gas comprising precursor, reactant, or both, is provided to the plasma source 825 by means of a gas line 860. Active species such as ions and radicals generated by the plasma 820 from the process gas are guided to the reaction chamber 810.

From the above discussion, it should be understood that the inventors were attempting to design new underlayer (UL) materials of high sensitivity for use, for example, in the EUV spectral region in order to improve the EUV absorbance and provide a cost efficient solution. The layers of different elements that have high photoabsorption cross sections can be included, in some cases, in the stack to increase the EUV sensitivity.

In this regard, the inventors understood that high-z materials have often been considered candidates to be used for increasing EUV absorption. The EUV absorbance cross section is relatively high on a per mole (or by atom) basis, and these elements include Te, Sb, Sn, In, and the like. The inventors recognized, though, that if EUV absorbance is considered, instead, by mass of the elements (or per gram), the lighter (or low-z) elements, such as Mg and Na, have high EUV absorbance cross sections. In some cases, the lighter elements, like Mg and Na, have lighter weight so by mass they can have higher EUV absorbance than the heavier or high-z elements.

By selecting elements comprising a high EUV capture cross section by mass, absorber layers or underlayers can be formed that pack more lighter elements within a volume than can be achieved with high-z elements. As a result, there may be implementations in which Mg (F, Na, Al, and/or other materials discussed herein) may be more effective to provide a particularly high EUV sensitivity underlayer. This is likely the case because the sensitivity/absorption would depend on density of these elements per unit area, e.g., how many atoms per unit area or how much mass per unit area. It is possible that if one were to take mass into account, more Mg (or other lower-z material) may be provided in a particular volume by mass than counting by atoms. The use of these lighter elements also may be desirable as they have less toxicity in general and may, in some instances, outgas less toxic products during structure fabrication processes.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to the embodiments shown and described herein, such as alternative useful combinations of the elements described, may become apparent to those skilled in the art from the description. Such modifications and embodiments are also intended to fall within the scope of the appended claims.

We claim:

1. A method of forming an extreme ultraviolet (EUV) absorber layer on a surface of a substrate, the method comprising the steps of:
providing a substrate within a reaction space of a gas-phase reactor;
providing a precursor to the reaction space;
providing a reactant to the reaction space; and
forming an absorber layer on a surface of the substrate within the reaction space, the absorber layer comprising an element having a photoabsorption cross section at 91.5 eV on a per mass basis greater than 8×10⁵ cm²/g, a photoabsorption cross section at 91.5 eV on a per mole basis less than 5×10⁶ cm²/mol, and a Pauling electronegativity of less than 2.

2. The method of claim 1, wherein the element has a photoabsorption cross section at 91.5 eV on a per mass basis greater than 10×10⁵ cm²/g.

3. The method of claim 2, wherein the element has a photoabsorption cross section at 91.5 eV on a per mass basis greater than 12×10⁵ cm²/g.

4. The method of claim 3, wherein the element has a photoabsorption cross section at 91.5 eV on a per mass basis greater than 14×10⁵ cm²/g.

5. The method of claim 1, wherein the element is selected from the group consisting of: Mg, Na, and Al.

6. The method of claim 5, wherein the absorber layer comprises a chalcogenide or a halide of the element.

7. The method of claim 1, wherein the absorber layer further comprises a dopant selected from the group consisting of I, Te, Cs, Sb, Sn, In, Bi, Ag, Pb, Au, Pt, and Ir.

8. The method of claim 1, wherein the absorber layer comprises a cation forming element and an anion forming element.

9. The method of claim 1, further comprising a step of forming an EUV photoresist layer overlying the absorber layer.

10. The method of claim 9, wherein the EUV photoresist layer comprises at least one of a molecular resist, a metal oxide resist, and a chemically amplified resist.

11. The method of claim 1, wherein the step of forming the absorber layer comprises plasma enhanced atomic layer deposition or plasma enhanced chemical vapor deposition.

12. The method of claim 1, wherein the precursor comprises an alkylamido compound with a metal center and one or more independently selected alkyl amine ligands or the precursor comprises a ligand selected from the group consisting of cyclopentadienyl, alkylamide, alkoxide, alkyl, halide, amidinate, diazadiene, and carbonyl.

13. A structure for forming patterned features using extreme ultraviolet (EUV) radiation, the structure comprising:
a substrate; and
an absorber layer formed overlying the substrate, wherein the absorber layer comprises an element selected from the group consisting of: F, Mg, Na, and Al.

14. The structure of claim 13, wherein the absorber layer comprises an oxide or a fluoride of the element.

15. The structure of claim 13, wherein the element has a photoabsorption cross section at 91.5 eV on a per mass basis greater than 8×10⁵ cm²/g, a photoabsorption cross section at 91.5 eV on a per mole basis less than 5×10⁶ cm²/mol, and a Pauling electronegativity of less than 2

16. The structure of claim 13, wherein the absorber layer further comprises a dopant with a photoabsorption cross section at 91.5 eV on a per mole basis greater than 2×10⁶ cm²/mol.

17. The structure of claim 13, further comprising an EUV photoresist layer overlying the absorber layer.

18. A structure for forming patterned features using extreme ultraviolet (EUV) radiation, the structure comprising:
a substrate; and
an absorber layer formed overlying the substrate, wherein the absorber layer comprises an element selected from the group consisting of Mn, Fe, Co, Ni, Cu, Zn, Ga, Ge, and As.

19. The structure of claim 18, wherein the element has a photoabsorption cross section at 91.5 eV on a per mass basis greater than 6×10⁵ cm²/g and a photoabsorption cross section at 91.5 eV on a per mole basis less than 5×10⁶ cm²/mol.

20. The structure of claim 18, wherein the absorber layer comprises an oxide or a fluoride of the element.
